(19) United States
(12) Patent Application Publication
(10) Pub. No.: US 2014/0042622 A1
(43) Pub. Date: Feb. 13, 2014

(54) Fine Pitch Package-on-Package Structure

(71) Applicants: Tsai-Tsung Tsai, Taoyuan City (TW); Chun-Cheng Lin, New Taipei City (TW); Ai-Tee Ang, Hsin-Chu City (TW); Yi-Da Tsai, Dongshi Township (TW); Ming-Da Cheng, Jhubei City (TW); Chung-Shi Liu, Hsin-Chu City (TW)

(72) Inventors: Tsai-Tsung Tsai, Taoyuan City (TW); Chun-Cheng Lin, New Taipei City (TW); Ai-Tee Ang, Hsin-Chu City (TW); Yi-Da Tsai, Dongshi Township (TW); Ming-Da Cheng, Jhubei City (TW); Chung-Shi Liu, Hsin-Chu City (TW)

(73) Assignee: TAIWAN SEMICONDUCTOR MANUFACTURING COMPANY, LTD., Hsin-Chu (TW)

(21) Appl. No.: 13/572,417

(22) Filed: Aug. 10, 2012

(51) Int. Cl. H01L 23/498

(52) U.S. Cl. 257/738; 257/E23.069

(57) ABSTRACT

A package-on-package (PoP) device including a substrate having an array of contact pads arranged around a periphery of the substrate, a logic chip mounted to the substrate inward of the array of contact pads, and non-solder bump structures mounted on less than an entirety of the contact pads available.

### BACKGROUND

As the demand for smaller electronic products grows, manufacturers and others in the electronics industry continually seek ways to reduce the size of integrated circuits used in the electronic products. In that regard, three-dimensional type integrated circuit packaging techniques have been developed and used.

One packaging technique that has been developed is Package-on-Package (PoP). As the name implies, PoP is a semiconductor packaging innovation that involves stacking one package on top of another package. A PoP device may combine vertically discrete memory and logic packages. In PoP package designs, the top package may be interconnected to the bottom package using solder balls in a ball grid array (BGA). Unfortunately, the BGA solder balls have pitch and size limitations.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a plan view of a package-on-package (PoP) device having ball grid array (BGA) solder balls arranged around a logic chip;

FIG. 2 illustrates a cross sectional view of the PoP device of FIG. 1 taken generally along line 2-2;

FIG. 3 illustrates a PoP device having non-solder bump structures arranged around a logic chip;

FIG. 4 illustrates a cross sectional view of the PoP device of FIG. 3 taken generally along line 4-4;

FIG. 5a illustrates an embodiment non-solder bump structure in the form of a stud bump;

FIG. 5b illustrates an embodiment non-solder bump structure in the form of a copper ball;

FIG. 6 illustrates a legend identifying an exposed contact pad and the non-solder bump structures (i.e., contact devices) of FIGS. 5a-5b;

FIG. 7 illustrates an embodiment pattern of the exposed contact pads relative to the non-solder bump structures;

FIG. 8 illustrates an embodiment pattern of the exposed contact pads relative to the non-solder bump structures; and

FIG. 9 illustrates an embodiment pattern of the exposed contact pads relative to the non-solder bump structures.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative and do not limit the scope of the disclosure.

The present disclosure will be described with respect to preferred embodiments in a specific context, namely a package-on-package (PoP) semiconductor device. The concepts in the disclosure may also apply, however, to other semiconductor structures or circuits.

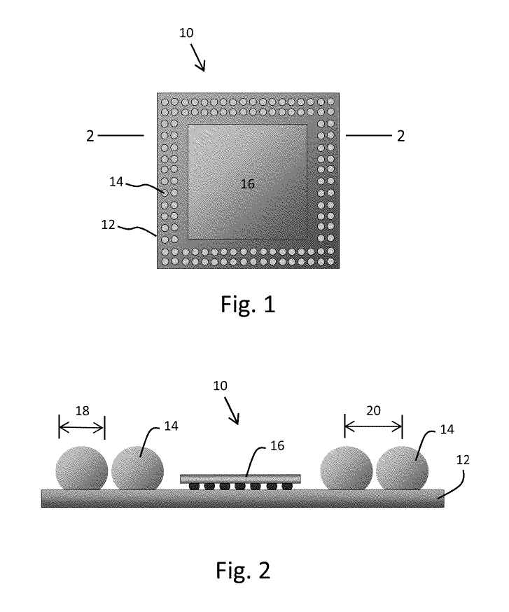

Referring to FIG. 1, a PoP device 10 is illustrated. The PoP device 10 generally includes a substrate 12 (e.g., a printed circuit board (PCB)) supporting ball grid array (BGA) solder balls 14 arranged around a logic chip 16. As shown in FIG. 2, each of the solder balls 14 has a diameter 18 of about 150 μm to about 250 μm. A ball pitch 20 between adjacent solder balls 14 is between about 300 μm to about 400 μm. While these dimensions may be suitable for existing PoP devices, a significant reduction in one or both of these dimensions would be desirable for more advanced PoP devices.

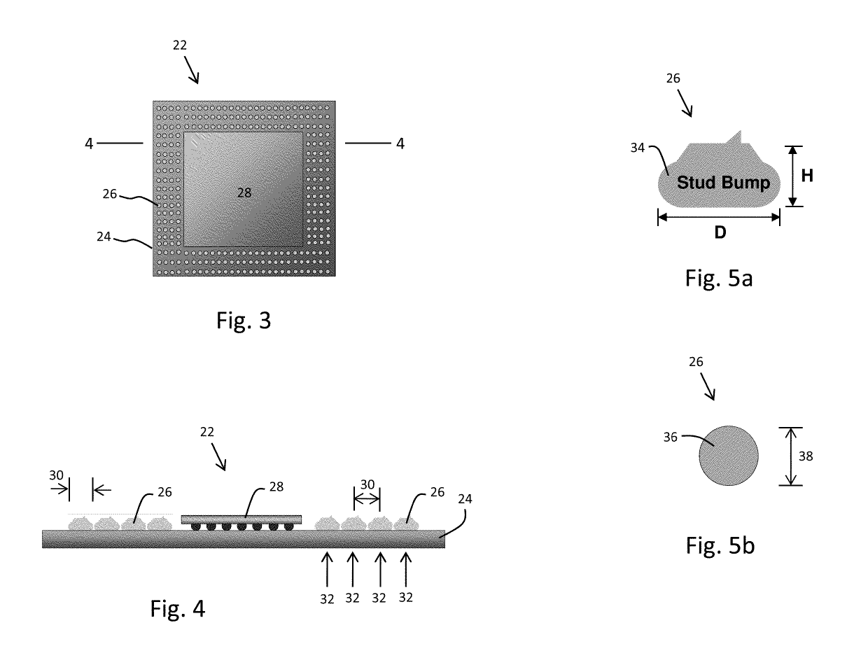

Referring now to FIG. 3, a PoP device 22 is illustrated. The PoP device 22 generally includes a substrate 24 (e.g., a printed circuit board (PCB)) supporting non-solder bump structures 26 (i.e., contact devices) arranged around a logic chip 28. It has been discovered that using the non-solder bump structures 24 of FIG. 3 instead of the BGA solder balls 14 of FIG. 2 permits package dimensions to be reduced. Therefore, replacing the BGA solder balls 14 of FIG. 2 with the non-solder bump structures 24 allows for a smaller overall package.

In an embodiment, the logic chip 28 of FIG. 3 may be one or more standard logic integrated circuits (ICs) such as, for example, central processing unit (CPU), Microcontroller unit (MCU), application processor, System Core Logic Chipsets, Graphics & Imaging Controllers, Mass Storage Controllers and I/O Controllers. In an embodiment, the logic chip 28 may be one or more application specific integrated circuits (ASICs) such as, for example, a Programmable Device based Design (PDD), a Gate Array based Design (GAD), a Cell-Based IC (CBIC), and a Full Customer Design (FCD).

As shown in FIG. 4, in an embodiment a pitch 30 between adjacent non-solder bump structures 26 is below the pitch 20 of 300 μm when BGA solder balls 14 are employed. Indeed, in an embodiment the pitch 30 between adjacent non-solder bump structures 26 in FIG. 4 is less than about 100 μm. While four rows 32 of non-solder bump structures 26 are depicted in FIG. 4, more or fewer rows may be included in the PoP device 10.

Referring now to FIG. 5a, an embodiment non-solder bump structure 26 in the form of a stud bump 34 is illustrated. The stud bump 34 may be formed through, for example, a wire bonding process. As shown, the stud bump 34 has a height, H, that is less than a width, W. The particular dimensions for the height and the width depend on the selection of wires in the wire bonding process. Regardless, the stud bump 34 is generally smaller than the BGA solder balls 14 of FIG. 2 in at least one dimension or direction. The stud bump 34 may be formed from a variety of suitable metallic non-solder materials including, but not limited to, gold, silver, copper, aluminum, or alloys thereof.

Referring now to FIG. 5b, an embodiment non-solder bump structure 26 in the form of a copper bump 36 is illustrated. A diameter 38 of the copper bump 34 is generally less than the diameter of the BGA solder balls 14 depicted in FIG. 2. In an embodiment, the bump structure 26 may also be a gold ball, a silver ball, or an aluminum ball, each of which are similar to the copper ball 36 depicted in FIG. 5b. The bump structure 26 may also be formed from suitable metallic non-solder alloys.

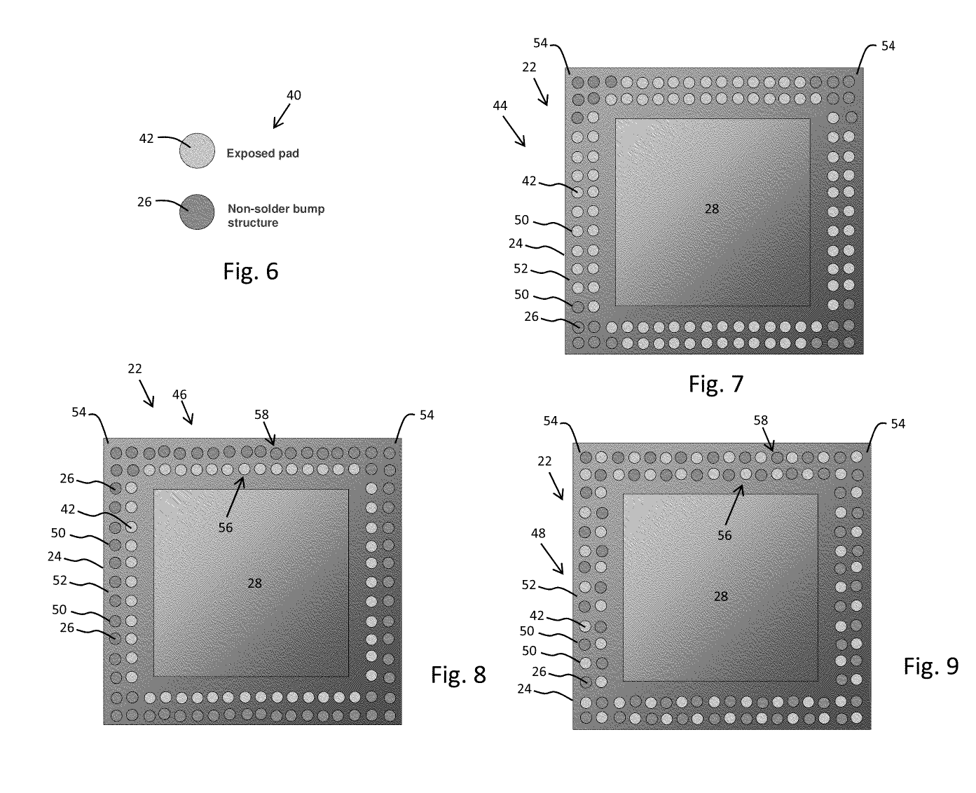

Referring now to FIG. 6, a legend 40 identifying an exposed contact pad 42 and the non-solder bump structures 26 of FIGS. 5a-5b is provided. With reference to the legend 40 of FIG. 6, embodiment patterns 44, 46, 48 of the exposed contact pads 42 relative to the non-solder bump structures 26 are illustrated in FIGS. 7-9. Despite the specific patterns 44, 46, 48 depicted in FIGS. 7-9, other patterns may be employed.

As will be more fully explained below, the non-solder bump structures 26 are mounted on less than an entirety of the contact pads 50 available on the substrate 24. Indeed, some of the contact pads 50 are covered by, or have mounted thereon, one of the non-solder bump structures 26. Those contact pads 50 that are not supporting one of the non-solder bump structures 26 are referred to as the exposed contact pads 42 as identified in the legend 40 of FIG. 6. In an embodiment, a thin layer of solder film is disposed beneath the non-solder bump structures 26 and over the exposed contact pads 42.

As shown in FIG. 7, the substrate 24 has an array of the contact pads 50 generally arranged around a periphery 52 of the substrate 24. In addition, the logic chip 28 is mounted to the substrate 24 inward of the array of contact pads 50. As shown, some of the contact pads 50 are exposed contact pads 42 while others of the contact pads 50 have one of the non-solder bump structures 26 mounted thereon. Referring to FIG. 7, in an embodiment the non-solder bump structures 26 are mounted on only the contact pads 50 disposed on corners 54 of the substrate 24. In other words, the non-solder bump structures 26 are arranged on the corners 54 of the PoP device 22.

Referring now to FIG. 8, in an embodiment the array of contact pads 50 comprises an inner ring 56 of the contact pads 50 concentric with an outer ring 58 of contact pads 50. In an embodiment, the non-solder bump structures 26 are mounted on each of the contact pads 50 in the outer ring 58 and on only the contact pads 56 forming the corners 54 of the inner ring 56. Referring now to FIG. 9, in an embodiment the non-solder bump structures 26 are mounted on only alternate contact pads 50 in each of the inner ring 56 and outer rings 58. Moreover, the non-solder bump structures 26 mounted on the inner ring 56 are offset from the non-solder bump structures 26 mounted on the outer ring 58 by one of the contact pads 50.

In an embodiment, the bump structures 26 may be arranged in a symmetric pattern, a non-symmetric pattern, or a combination thereof. In other words, the bump structures 26 may be mounted on the contact pads 50 in any of a variety of different configurations.

In each of FIGS. 7-9, the array of contact pads 50 comprises a square inner ring 56 of contact pads 50 concentric with a square outer ring 58 of contact pads 50. Even so, other configurations may be employed. In addition, more or fewer rings of contact pads 50 may be employed in other embodiments.

A package-on-package (PoP) device including a substrate having an array of contact pads arranged around a periphery of the substrate, a logic chip mounted to the substrate inward of the array of contact pads, and non-solder bump structures mounted on less than an entirety of the contact pads available.

A package-on-package (PoP) device including a printed circuit board having an array of contact pads arranged in concentric rings around a periphery of a substrate, a logic chip mounted to the substrate in a flip-chip mounting configuration and inward of the array of contact pads, and non-solder bump structures mounted on fewer than all of the contact pads.

A method of forming package-on-package (PoP) device including arranging an array of contact pads around a periphery of a substrate, mounting a logic chip to the substrate inward of the array of contact pads, and mounting non-solder bump structures on less than an entirety of the contact pads.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A device, comprising:
a substrate having an array of contact pads arranged around a periphery of the substrate, the contact pads directly adjacent the periphery equally spaced apart around an entirety of the periphery;
a logic chip mounted to the substrate inward of each of the contact pads in the array and disposed on the substrate; and
non-solder bump structures mounted on less than an entirety of the contact pads available.

2. The device of claim 1, wherein the non-solder bump structures comprise stud bumps formed through a wire bonding process.

3. The device of claim 1, wherein the non-solder bump structures comprise copper balls.

4. The device of claim 1, wherein the non-solder bump structures are formed from one of gold, silver, copper, and aluminum.

5. The device of claim 1, wherein a pitch between adjacent ones of the non-solder bump structures is less than or equal to 100 μm.

6. The device of claim 1, wherein a height of the non-solder bump structures is less than a width of the non-solder bump structures.

7. The device of claim 1, wherein the non-solder bump structures are mounted on only the contact pads disposed on corners of the substrate.

8. The device of claim 1, wherein the array of contact pads comprises an inner ring of contact pads concentric with an outer ring of contact pads, the non-solder bump structures mounted on each of the contact pads in the outer ring and on only the contact pads forming corners of the inner ring.

9. The device of claim 1, wherein the array of contact pads comprises an inner ring of contact pads concentric with an outer ring of contact pads, the non-solder bump structures mounted on only alternate contact pads in each of the inner ring and outer rings.

10. The device of claim 9, wherein the non-solder bump structures mounted on the inner ring are offset from the non-solder bump structures mounted on the outer ring by one of the contact pads.

11. The device of claim 1, wherein the array of contact pads comprises a square inner ring of contact pads concentric with a square outer ring of contact pads.

12. The device of claim 1, wherein the non-solder bump structures are mounted on less than an entirety of the contact pads in a non-symmetrical pattern.

13. A device, comprising:
a printed circuit board having an array of contact pads arranged in concentric rings around a periphery of the printed circuit board, the contact pads directly adjacent the periphery equally spaced apart around an entirety of the periphery;
a logic chip mounted to the printed circuit board in a flip-chip mounting configuration and inward of each of the contact pads in the array and disposed on the printed circuit board; and
non-solder bump structures mounted on fewer than all of the contact pads.

14. The device of claim 13, wherein the non-solder bump structures comprise one of stud bumps and copper balls.

15. The device of claim 13, wherein the non-solder bump structures are formed from one of gold, silver, copper, and aluminum and a pitch between adjacent ones of the non-solder bump structures is less than or equal to 100 μm.

16. The device of claim 13, wherein the non-solder bump structures are mounted on only the contact pads disposed on corners of the substrate.

17. The device of claim 13, wherein the array of contact pads comprises an inner ring of contact pads concentric with an outer ring of contact pads, the non-solder bump structures mounted on each of the contact pads in the outer ring and on only the contact pads forming corners of the inner ring.

18. The device of claim 13, wherein the array of contact pads comprises an inner ring of contact pads concentric with an outer ring of contact pads, the non-solder bump structures mounted on only alternate contact pads in each of the inner ring and outer rings.

19. The device of claim 13, wherein the array of contact pads comprises an outer ring of contact pads concentric with a plurality of inner rings of contact pads, the non-solder bump structures mounted on each of the contact pads in the outer ring.

20. The device of claim 13, wherein the non-solder bump structures are mounted on fewer than all of the contact pads in a non-symmetrical pattern.
